(19) United States
(12) Patent Application Publication
(10) Pub. No.: US 2006/0246234 A1
(43) Pub. Date: Nov. 2, 2006

(54) Photomask assembly incorporating a metal/scavenger pellicle frame

(75) Inventors: Douglas Meyers, Calabasas, CA (US); Rahul Ganguli, Agoura Hills, CA (US); Troy Robinson, Camarillo, CA (US); Robert Gump, Camarillo, CA (US); Steven Colbern, Ventura, CA (US); Fikret Kirkbir, Los Angeles, CA (US)

Correspondence Address: SHEPPARD, MULLIN, RICHTER & HAMPTON LLP, 333 SOUTH HOPE STREET, 48TH FLOOR, LOS ANGELES, CA, 90071-1448, US

(73) Assignee: Yazaki Corporation

(21) Appl. No.: 11/407,691

(22) Filed: Apr. 19, 2006

Related U.S. Application Data
(60) Provisional application No. 60/673,539, filed on Apr. 20, 2005.
(60) Provisional application No. 60/686,527, filed on May 31, 2005.

(51) Int. Cl. G03F 1/14

(52) U.S. Cl. 428/14; 430/5; 430/30; 428/194; 430/311; 428/421; 428/422

(57) ABSTRACT

A photomask assembly is disclosed having a photomask substrate and a composite pellicle frame that includes both a metallic frame component and a scavenger component. The metallic frame component has a cross-sectional thickness of at least 100 micrometers in all directions, and the volume percentage of the scavenger component relative to the overall volume of the composite frame is in the range of 0.1 to 95%. The scavenger component has a gas permeability to oxygen or nitrogen greater than about 10 ml·mm/cm²·min·MPa, an average pore size between 0.001 and 10 micrometers, and a pore surface area greater than 10 m²/g. This configuration enables the pellicle frame to have sufficient strength to withstand stresses encountered during normal use, yet also to have the capability of scavenging impurity molecules from the space adjacent to the photomask substrate. In a separate and independent feature of the invention, the scavenger component comprises at least one metal oxide selected from the group consisting of oxides of aluminum, boron, cerium, cobalt, copper, erbium, hafnium, lanthanum, neodymium, praseodymium, scandium, silicon, titanium, yttrium, zirconium, and mixtures thereof. Preferably, the metal oxide is an oxide of zirconium, yttrium, or mixtures thereof.

### CROSS-REFERENCE TO RELATED APPLICATIONS

Priority is claimed from co-pending U.S. Provisional Patent Application Ser. No. 60/673,539, filed Apr. 20, 2005, and Ser. No. 60/686,527, filed May 31, 2005, which are incorporated herein by reference.

### BACKGROUND OF THE INVENTION

This invention relates generally to photomask assemblies used in a lithographic process and, more particularly, to photomask assemblies incorporating pellicle frames configured to scavenge harmful chemicals from the pellicle space adjacent to a photomask substrate.

In the semiconductor industry, intricate patterns of electronic chips are generally made using photolithographic processes. These processes utilize photomask assemblies, in combination with laser exposure systems, to transfer patterns onto electronic chips. FIG. 1 shows the components of a conventional photomask assembly 10, including a pellicle 12, a frame 14, antireflective films 16, a liquid coating 18, a photomask substrate 20, mounting adhesive 22, a cover adhesive 24, glue 26, and a release liner 28.

The photomask substrate 20, typically made of synthetic silica, is printed with a pattern of an electronic circuit or chip (not shown in FIG. 1) to be produced. The pellicle 12, typically made of a soft transparent polymer, functions to protect the patterned surface of the photomask substrate from outside contaminants, thereby extending the substrate's useful lifetime and decreasing the production costs of the electronic chips. Both surfaces of the pellicle are coated with antireflective films 16, to increase the transmittance of the laser light. The frame 14, typically made of anodized aluminum, functions to support the polymer pellicle above the substrate so as to define a pellicle space 32. The frame typically has a rectangular shape, although it alternatively can have a polygonal, oval, or circular shape. The frame and pellicle typically are mounted on the photomask substrate using any of a variety of adhesives. The release liner 28, typically made of a polymer material, functions to facilitate easy removal of the pellicle, allowing various components of the assembly to be cleaned or replaced. The liquid coating 18 is applied to the inner surface of the frame, to capture particulate matter present in the pellicle space 32.

The pattern on the photomask substrate 20 is repetitively transferred onto the surface of a succession of electronic chips (not shown in FIG. 1) by continuously exposing the photomask substrate to ultraviolet (UV) or deep-ultraviolet (DUV) light at a specified wavelength. Conventional photolithography systems use laser light sources operating at wavelengths of 436 nm, 365 nm, 248 nm, and more recently 193 nm. In general, lower wavelengths provide a finer pattern resolution. In the future, 157 nm lasers may be used to develop even finer patterns.

The light from such high energy lasers can heat the photomask assembly and trigger certain undesired photochemical and thermal reactions in the pellicle space. Over time, these reactions can cause the formation and growth of defects (or contaminants) under the pellicle, on the surfaces of photomask assembly components, eventually destroying the patterns transferred to the chips. These defects are described as “haze,” “particles,” or “crystals.”

Considerable research has been conducted to determine the cause(s) of this contamination. Bhattacharyya et al. disclose in a publication entitled “Investigation of Reticle Defect Formation in DUV Lithography,” Proceedings of SPIE Vol. 4889, 22^{nd} Annual BACUS Symposium on Photomask Technology, 478-487 (2002), that defect formation mechanisms are affected by several factors, including the photomask assembly components described above, the assembly container, the storage and fabrication environment, the exposure system environment, residuals from the cleaning of the assembly components, repetitive exposure to the laser light, and the wavelength of the laser. The Bhattacharyya et al. publication reports that the number of defects increases drastically after about 700 exposures to a 193 nm laser. It also reports that these defects may comprise ammonium sulfate (NH₄)₂SO₄, cyanuric acid C₃N₃(OH)₃, and organic compounds. It also reports that cyanuric acid crystals may form and grow by reaction of residues of ammonium hydroxide cleaning solution with ambient carbon dioxide and water vapor diffusing through the photomask assembly. It suggests that outgassing of cyanoacrylate pellicle film adhesive under the laser exposure may also be responsible for formation of cyanuric acid contamination.

The reticles are commonly cleaned using sulfuric acid, hydrogen peroxide, and ammonium hydroxide. These chemicals may leave residues on and/or react with the reticle surfaces during the cleaning process and later cause formation and growth of ammonium sulfate crystals under continued laser exposure. This results in defects, as described by Grenon et al. in a publication entitled “Reticle Surface Contaminants and Their Relationship to Sub-Pellicle Particle Formation” Proceedings of SPIE Vol. 5256, 23^{rd} Annual BACUS Symposium on Photomask Technology, 1103-1110 (2003). Grenon et al. also report that the number of defects increases linearly with increasing exposure energy, for a 248-nm laser, whereas it increases exponentially for a 193-nm laser.

It also has been demonstrated experimentally that the number of defects on the backside of the photomask substrate is higher than those on the pattern side (see, Grenon et al., “Reticle Surface Contaminants and Their Relationship to Sub-Pellicle Particle Formation,” Proceedings of SPIE Vol. 5375, Metrology, Inspection, and Process Control for Microlithography, 355-362, 2004).

Some defects on chrome-on-glass-type reticles were found to comprise hydrocarbons, as described by B/hattacharyya et al. in a publication entitled “An Investigation of a New Generation of Progressive Mask Defects on the Pattern Side of Advanced Photomasks,” Proceedings of SPIE Vol. 5752, Metrology, Inspection, and Process Control for Microlithography XIX, 1257-1265 (2005).

In summary, defects might form and grow on the reticle surfaces due to the presence of one or more chemicals such as ammonium ions, sulfate ions, ammonium sulfate, cyanuric acid, water vapor, carbon dioxide, and hydrocarbons. These chemicals currently are considered the main sources of defect formation and growth. However, future research might reveal the presence of other defect-forming chemicals or other defect formation and growth mechanisms. Such chemicals might diffuse into the pellicle space from the outside environment and/or might form by degassing or degradation of the assembly components. The laser exposure wavelength might affect the defect formation and growth mechanism. Different chemicals might also form under different exposure wavelengths. The chemicals that cause the formation and growth of defects are hereafter referred to as harmful chemicals.

The defect formation and growth may partially or completely be avoided by purging the pellicle space with an inert gas such as nitrogen after the assembly has been fabricated and/or during the laser exposure. This purging may remove the harmful chemicals mentioned above. As explained in a publication by Cullins, entitled “LITJ360-157 nm Mask Materials,” International SEMATECH's 157 nm Technical Data Review, December 2001, some incidental purging may occur through the pellicle itself, because the pellicle is formed of a polymer material having some permeability. However, this purging is thought to be too slow to eliminate all the problems discussed above within a reasonable processing time. Also, it is known that soft polymer pellicles can easily degrade when repetitively exposed to light from UV and DUV lasers, causing considerable reduction in light transmittance. In addition, soft polymer pellicles cannot easily be cleaned and handled.

U.S. Pat. No. 6,524,754 to Eynon suggests that hard pellicles formed of synthetic or fused silica can be substituted for soft polymer pellicles. Although such hard pellicles can solve the cleaning, handling, and degradation problems, they are impermeable to gases and thereby not suitable for purging through the pellicle.

Modifications to reticle cleaning processes have thus far had little positive impact on the problem, as described by Marmillion et al. in a publication entitled “Advanced Photomask Cleaning,” Proceedings of SPIE Vol. 5567, 24^{th} Annual BACUS Symposium on Photomask Technology, 506-510 (2004).

Proposals have been made to position chemical filters at vent holes incorporated into the frame structure. However, these proposals fail to disclose a frame that can effectively remove the harmful chemicals from the pellicle space and at the same time fulfill strict specification requirements of the semiconductor industry for the photomask assembly, without causing additional problems.

An effective alternative solution would be welcomed enthusiastically by the semiconductor industry. It should, therefore, be appreciated that there is a continuing need for a photomask assembly incorporating a pellicle frame having sufficient strength to withstand stresses encountered during normal use, yet also having the capability of scavenging impurity molecules from the space adjacent to the photomask substrate. The present invention fulfills this need and provides further related advantages.

### SUMMARY OF THE INVENTION

The present invention resides in an improved photomask assembly incorporating a pellicle frame having sufficient strength to withstand stresses encountered during normal use, yet also having the capability of scavenging impurity molecules from the space adjacent to the photomask substrate. More particularly, the pellicle frame has a composite structure that includes a metallic frame component and a scavenger component. The metallic frame component has a cross-sectional thickness of at least 100 micrometers in all directions, and the scavenger component has a gas permeability to oxygen or nitrogen greater than about 10 ml·mm/cm²·min·MPa, an average pore size between 0.001 and 10 micrometers , and a pore surface area larger than 10 m²/g. In addition, the volume percentage of the scavenger component relative to the overall volume of the composite frame is in the range of 0.1 to 95%.

In a more detailed feature of the invention, the volume percentage of the scavenger component relative to the overall volume of the composite more preferably is in the range of 1 to 80%, more preferably still is in the range of 10 to 70%, and most preferably is in the range of 20 to 60%.

In a separate and independent feature of the invention, the scavenger component comprises at least one metal oxide selected from the group consisting of oxides of aluminum, boron, cerium, cobalt, copper, erbium, hafnium, lanthanum, neodymium, praseodymium, scandium, silicon, titanium, yttrium, zirconium, and mixtures thereof. More preferably, the metal oxide is selected from the group consisting of oxides of zirconium, yttrium, and mixtures thereof. Further, the scavenger component preferably comprises an oxide of zirconium, yttrium, or mixtures thereof, in a weight percentage of preferably at least 0.1, more preferably at least 1, and most preferably least 10.

In other more detailed features of the invention, the scavenger component has a gas permeability to oxygen or nitrogen more preferably greater than about 40 ml·mm/cm²·min·MPa, and most preferably greater than about 70 ml·mm/cm²·min·MPa. The scavenger component also has an average pore size more preferably between 0.01 and 1 micrometer, and most preferably between 0.08 and 1 micrometer. Further, the scavenger component has a pore surface area more preferably greater than 25 m²/g, and most preferably greater than 70 m²/g.

In yet other more detailed features of the invention, the scavenger component is configured to scavenge at least one harmful chemical in an amount greater than 0.01 weight percent of the scavenger component, or more preferably in an amount greater than 0.03 weight percent of the scavenger component.

In other more detailed features of the invention, the metallic frame comprises a metal selected from the group consisting of aluminum, steel, titanium, titanium alloys, molybdenum, nickel, nickel alloys, chromium, chromium alloys, copper, copper alloys, and mixtures thereof. The cross-sectional thickness of the metallic frame is at least 500 micrometers, or more preferably at least 1,000 micrometers, in all directions. In addition, the metallic frame has a thermal expansion coefficient less than 20 ppm/° C., or more preferably less than 10 ppm/° C.

In yet other more detailed features of the invention, the metallic frame is porous, with an average pore size between 0.001 and 10 micrometers, or more preferably between 0.01 and 1 micrometer, and most preferably between 0.08 and 1 micrometer. In addition, the metallic frame has a gas permeability to oxygen or nitrogen greater than about 10 ml·mm/cm²·min·MPa, or more preferably greater than about 40 ml·mm/cm²·min·MPa, and most preferably greater than about 70 ml·mm/cm²·min·MPa.

Other features and advantages of the present invention should become apparent from the following description of the preferred embodiments, taken in conjunction with the accompanying drawings, which illustrate, by way of example, the principles of the invention.

### BRIEF DESCRIPTION OF THE DRAWINGS

FIG. 1 is a simplified cross-sectional view, not to scale, of a prior art photomask assembly incorporating a photomask substrate, a metallic pellicle frame, and a pellicle.

FIGS. 2(a)-(d) are cross-sectional views of four alternative embodiments of a composite pellicle frame in accordance with the invention.

FIGS. 3(a) and (b) are cross-sectional and plan views, respectively, of a composite pellicle frame in accordance with yet another embodiment of the invention.

FIGS. 4(a) and (b) are isometric and detailed cross-sectional views, respectively, of a composite pellicle frame in accordance with yet another embodiment of the invention.

FIGS. 5(a) and (b) are isometric and detailed cross-sectional views, respectively, of a composite pellicle frame in accordance with yet another embodiment of the invention.

FIGS. 6(a) and (b) are side elevational and fragmentary top plan views, respectively, of the composite pellicle frame of FIGS. 4(a) and (b).

### DETAILED DESCRIPTION OF THE PREFERRED EMBODIMENTS

The present invention is embodied in an improved photomask assembly incorporating a pellicle frame having sufficient strength to withstand stresses encountered during normal use, yet also having the capability of scavenging (gettering) harmful chemicals from the pellicle space. More particularly, the pellicle frame comprises both a metallic component and a scavenger component, forming a composite frame as an alternative to a conventional all-metallic frame.

The scavenger component scavenges harmful chemicals and thereby minimizes the formation and growth of defects on photomask assembly surfaces during the laser exposure. The scavenger component is somewhat fragile, however, and therefore might have inadequate mechanical properties to function alone as a pellicle frame. The metallic component of the composite frame forms a skeleton and thereby provides mechanical strength and structural support for the scavenger component. The metallic component can withstand the mechanical loads encountered during the frame's preparation, including its processing and incorporation into the photomask assembly as well as during the manufacturing of the electronic chip, including manual handling and cleaning exposure.

The composite pellicle frame may have any shape and size that can fit to a particular photomask assembly currently used or targeted for the future use by the semiconductor industry. The photomask substrate may be circular, oval, square, or rectangular in shape. Standard photomask substrates have dimensions of 12.5 cm×12.5 cm and 15 cm×15 cm. For future applications, photomask substrates having dimensions of 22.5 cm×22.5 cm are being targeted. The substrate thickness varies with application. Dimensions and shape of the patterned area of the photomask substrate also vary with application. Thus, the composite pellicle frame's shape and dimensions vary with the shapes and sizes of the photomask substrate and the patterned area. The composite frame is manufactured to fulfill these shape and dimensional requirements.

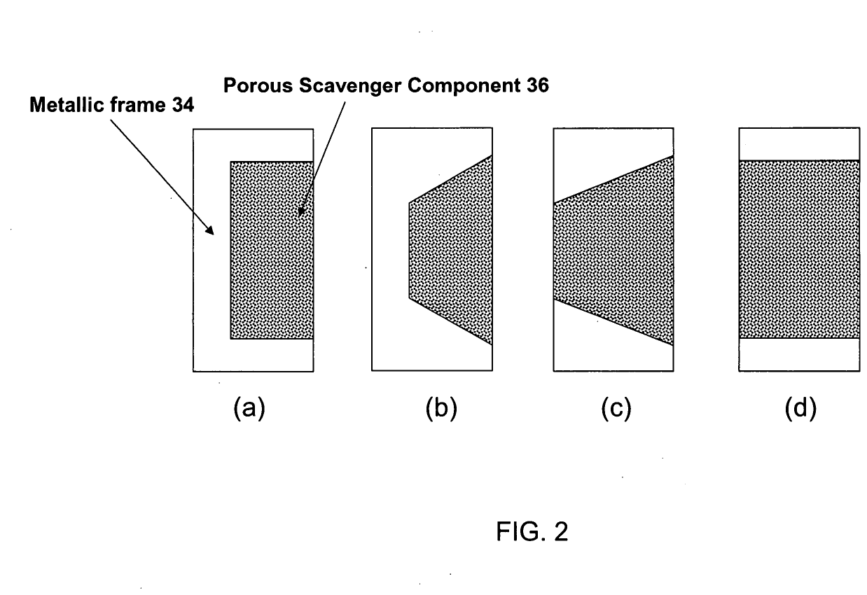

Numerous alternative configurations for a composite metal/scavenger pellicle frame in accordance with the invention are contemplated. Simplified cross-sectional views of several such configurations are depicted in FIGS. 2, 3, and 4. The configuration depicted in FIG. 2(a) includes a metallic frame 34 having cavities of rectangular cross-section formed in its inner walls, with a strip of scavenger component 36, of corresponding size and shape, located in each cavity. This configuration maintains an all-metal interface between the pellicle frame and the overlaying pellicle film (not shown in FIG. 2); therefore no changes in the current film-mounting process are needed. A modified configuration is depicted in FIG. 2(b), having cavities of trapezoidal cross-section instead of rectangular cross-section.

FIG. 2(c) depicts another configuration of a combined metal/scavenger pellicle frame in accordance with the invention, which includes trapezoidal cut-outs extending fully through the metallic frame 34 for retaining the scavenger components 36. This configuration can provide permeability through the porous scavenger material, as well as scavenging capability around the exterior of the photomask assembly. Defects occasionally form on the “backside,” i.e., non-patterned surface, of the photomask substrate, and locating the scavenger components on the outer surface of the pellicle frame might reduce this haze as well. Yet another configuration is depicted in FIG. 2(d), having rectangular openings machined fully through the metallic frame.

Configurations like those depicted in FIGS. 2(c) and 2(d), where the scavenger components extend from the frame's inner surface to its outer surface, may provide additional advantages over other configurations. Because the scavenger components are permeable, the pellicle space can be actively purged by the flow of an inert, non-harmful gas to remove the harmful chemicals. This active purging can be achieved by flowing the gas through the scavenger components, from the pellicle space to the photomask assembly's exterior. Purging also can be achieved by providing an inert gas at the photomask assembly's exterior and allowing the harmful chemicals to permeate through the porous scavenger components. Such types of purging may aid removal of the harmful chemicals by the scavenger components, increasing their efficiency.

Furthermore, configurations like those depicted in FIGS. 2(c) and 2(d), also might aid in solving another problem encountered by conventional photomask assemblies, which results from pressure gradients that can arise between the pellicle space and the photomask assembly's exterior. Such pressure gradients can occur, for example, during shipment of the assemblies using aircraft and also during one or more processing steps. Such pressure gradients can cause the flexible pellicle to bloat or cave, distorting its flatness to the laser exposure; in extreme cases, the pressure gradients even can cause the pellicle frame to rupture, thereby destroying the photomask assembly. Since the porous scavenger components are permeable to gases, the pressure difference between the pellicle space and the assembly's exterior can be equalized.

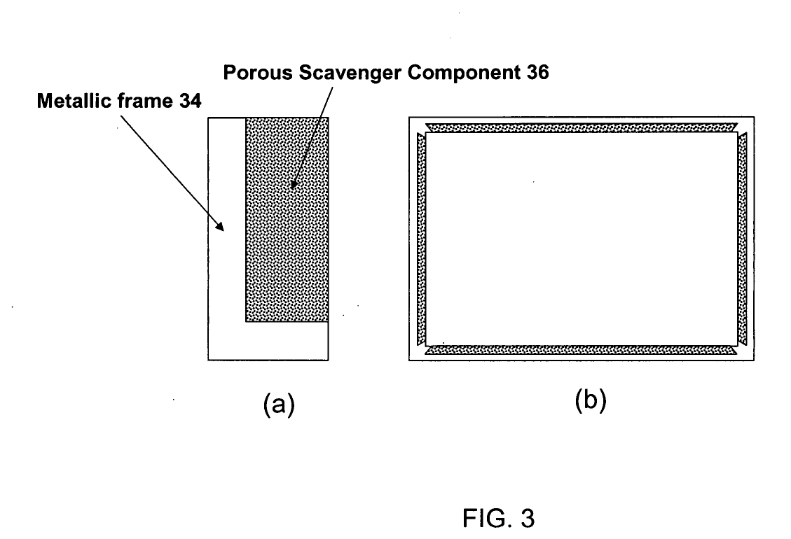

FIGS. 3(a) and (b) depict yet another configuration of a composite metal/scavenger pellicle frame in accordance with the invention. In this configuration, a slot is machined into the metallic frame from the top, rather than from the inner sidewall. Also, as shown in FIG. 3(b), the slots can be machined in a trapezoidal shape, such that the scavenger components are self-locking, thereby eliminating the need to use an adhesive to secure the components in place.

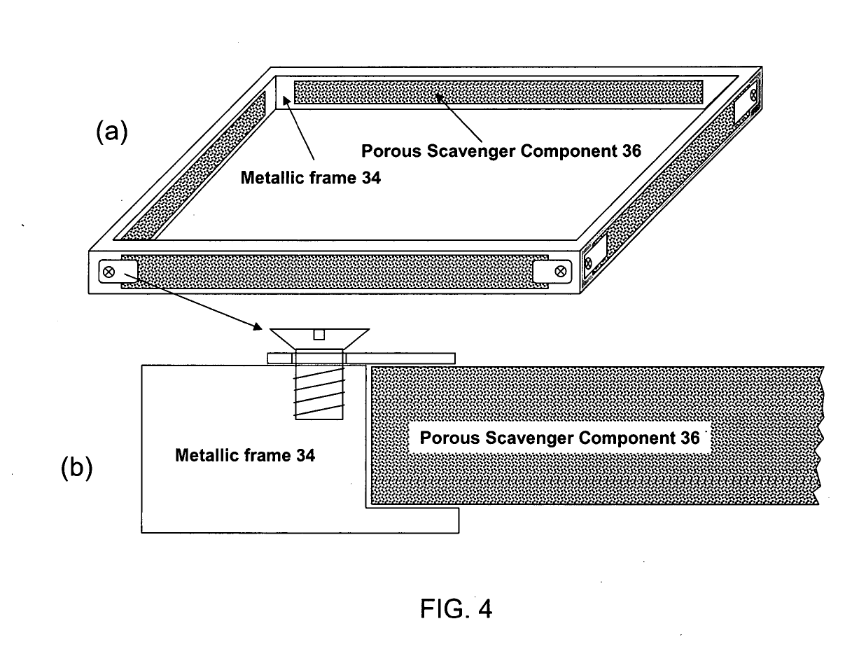

FIGS. 4(a) and (b) depict yet another configuration of a composite metal/scavenger pellicle frame 40 in accordance with the invention. In this configuration, the metallic frame 34 is machined to include stepped windows, with scavenger components 36 being held in place by screw-flange assemblies 38 on the frame's outside surface. The flanges hold the scavenger components in place from the outside, while the stepped configuration of the machined windows holds the components in place from the inside. This configuration, likewise, can eliminate the need to use an adhesive to secure the scavenger components in place. This configuration also can facilitate an easy replacement of the scavenger components.

In all of configurations disclosed above, the scavenger components can be manufactured with such precise dimensions that, when they are mechanically incorporated into the frame, they lock and seal themselves against the metallic frame walls without needing an adhesive. However, the use of an adhesive may also be considered for manufacturing of any configurations disclosed in this invention. This adhesive may aid in securing and sealing the scavenger components in the metallic frame, which are manufactured with less precise dimensions.

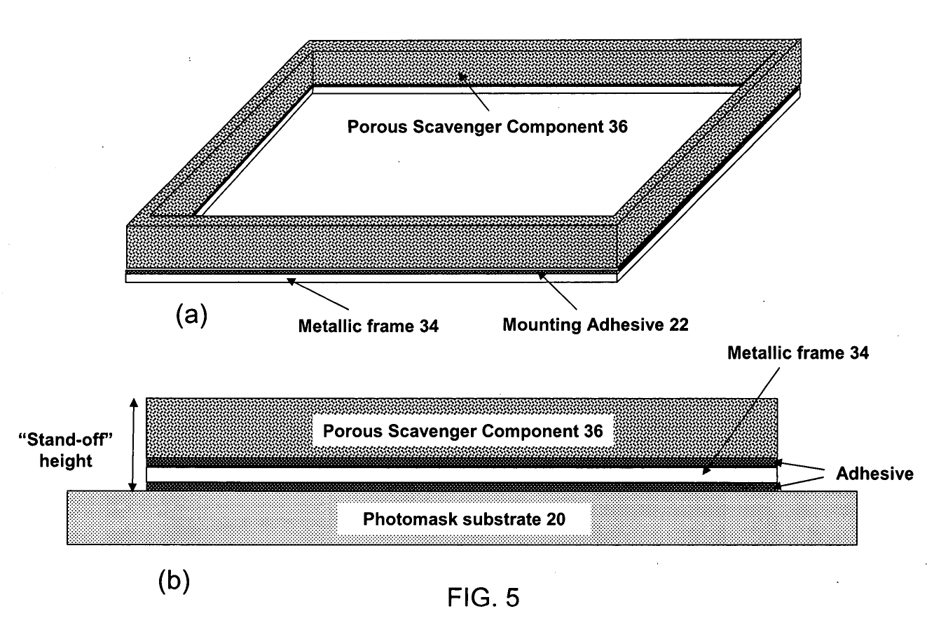

FIGS. 5(a) and (b) depict yet another configuration of a composite metal/scavenger pellicle frame in accordance with the invention. In this configuration, the pellicle frame includes a thin metallic frame 34 as the structural support member, with a scavenger component 36 mounted on top of it using an adhesive of the kind used to attach a conventional metallic frame to an underlying photomask (not shown). The thickness (height) of the metallic frame must be sufficient to withstand the mechanical loads encountered during normal use, and especially during demounting. It is expected that a thickness in the range of 1 to 2 mm will be required. The thickness (height) of the scavenger component can be calculated by subtracting the metallic base height and thicknesses of the two adhesive layers from the specified “stand-off height,” or required height, of the pellicle film over the photomask surface.

The configuration of FIGS. 5(a) and (b) is illustrated in the following example. A typical metallic frame may have a stand-off height of about 6.5±0.4 mm (including a frame having a thickness of about 6.0 mm and an adhesive layer having a thickness of 0.1-0.8 mm). If the metallic component of the composite pellicle frame of FIGS. 5(a) and (b) has a thickness of about 1.5 mm, and if the adhesive layers each have thicknesses of about 0.5 mm, then the allowable height of the scavenger component would be about 4.0 mm.

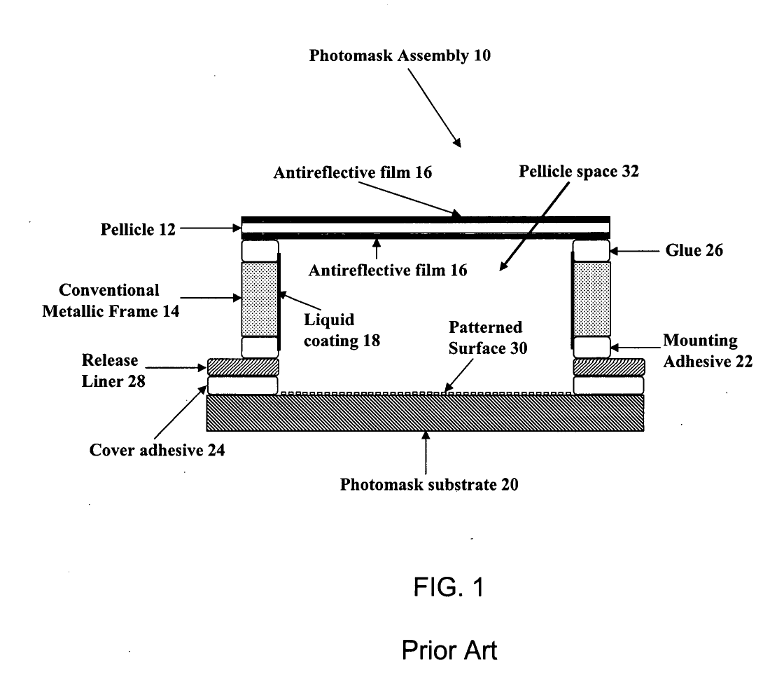

The configurations disclosed above are illustrative, only, and do not limit the composite frame's configuration. Thus, other configurations also may be useful and therefore are considered to be within the scope of this invention. For example, other useful configurations are disclosed in U.S. Patent Application Publication No. 2004/0137339 to Zhang et al., FIGS. 1-6 and paragraphs [0019] to [0033] and [0048] to [0063], and in U.S. Pat. No. 6,443,302 to Tanaka. The contents of this application and patent are incorporated by reference herein.

The scavenger components need not be restricted in size to lie wholly within the volume of the metallic frame; the scavenger components may protrude beyond the volume defined by the metallic frame. Such protrusions can increase the amount of the scavenger material and thereby increase the composite frame's scavenging capacity. If the scavenger components protrude inwardly into the pellicle space, their protrusion distance must not encroach on the patterned area in a way that would interfere with the exposure by the laser light. The scavenger components also can protrude outwardly into the cavity formed by the surrounding lithography equipment. Configurations in which the scavenger components protrude in both inward and outward directions also are useful and thereby are considered to be a part of this invention.

The metallic frame may be made of any metal having sufficient strength to withstand the stresses ordinarily encountered during manufacture and use of the photomask assembly. Examples of suitable metals include aluminum, steel (particularly stainless steel), titanium and titanium alloys, molybdenum, nickel, nickel alloys such as Inconel® (Ni—Cr) and Monel® (Ni—Cu), Invar® (Ni—Fe), Kovar® (Ni—Fe—Co), chromium and chromium alloys, copper and copper alloys (such as brass and bronze), and the like.

In one embodiment of the invention, the metallic component of the composite frame is aluminum. Aluminum is relatively inexpensive, easy to machine, and has sufficient strength to withstand the stresses ordinarily encountered during manufacture and use of the photomask assembly. Also, aluminum can be black-anodized to provide a black surface, improving the visibility of dust particles and minimizing reflections that might cause problems during mask inspections.

For some designs of composite pellicle frames incorporating both a metallic structure and one or more scavenger components, it might be desirable to maximize the volume of the scavenger component and minimize the volume of the metallic frame, to provide greater scavenging performance. This maximization is limited by the mechanical properties of the metal. If unduly thin, the metallic frame might have insufficient strength to withstand the stresses encountered during its manufacturing and use. Therefore, it might be beneficial to use a metal having higher strength and/or stiffness than aluminum. Examples of such alternative metals include steel (particularly stainless steel), titanium, titanium alloys, molybdenum, and nickel alloys such as Inconel® (Ni—Cr) and Monel® (Ni—Cu).

Yet for some applications, metals having a low coefficient of thermal expansion (CTE) might be desirable for use as the metallic frame material, to allow for significant temperature fluctuations within the exposure equipment. The thermal expansion or contraction of the pellicle frame caused by such fluctuations may deform the pellicle and/or the photomask substrate, distorting the image of the patterned area and thereby rendering the electronic chips useless. This is a particularly important issue for lithographic technologies that might operate at wavelengths lower than 193 nm. The risk of such distortions can be reduced by forming the metallic frame of a metal having a low CTE, e.g., Invar® or Kovar®. In one embodiment, the metallic frame preferably has a CTE lower than 20 ppm/° C. or, more preferably, lower than 10 ppm/° C.

In one embodiment of the invention, the metallic frame alternatively may be configured to be partially or completely porous, to facilitate a purging of harmful chemicals from the pellicle space. The purging through the porous sections of the metallic frame may aid the scavenger component in removing the harmful chemicals. The porous sections of the metallic frame also may act as vent holes, for equalizing the pellicle space pressure with the outside pressure. An example of a porous metallic frame is disclosed in U.S. Patent Application Publication No. 2004/0109153 to Vroman et al., which is incorporated by reference herein.

To remove the harmful chemicals by purging, the permeability of the metallic frame to nitrogen or oxygen preferably is higher than 10 ml·mm/cm²·min·MPa, more preferably is higher than 40 ml·mm/cm²·min·MPa, and most preferably is higher than 70 ml·mm/cm²·min·MPa. This high gas permeability can be achieved by preparing the metallic frame to have pores having average pore sizes larger than 0.001 micrometers, or more preferably larger than 0.01 micrometers, or most preferably larger than 0.08 micrometers. To prevent particles present in the environment surrounding the photomask assembly from migrating into the pellicle space, the average pore size of the metallic frame preferably is less than 10 micrometers, or more preferably less than 1 micrometer. Thus, the average pore size of the metallic frame preferably is in the range of 0.001 to 10 micrometers, more preferably in the range of 0.01 to 1 micrometers, and most preferably in the range of 0.08 to 1 micrometers.

The scavenging of the harmful chemicals can be achieved via several mechanisms. These mechanisms include adsorbing the chemicals onto the scavenger's surface, dissolving the chemicals into the scavenger's chemical structure, and reacting the scavenger with the harmful chemicals to convert them into non-harmful chemicals.

The scavenger component may incorporate any material(s) that is capable of scavenging harmful chemicals from the pellicle space. The scavenger may comprise more than just one material, and it may be a liquid, a viscous liquid, a high-surface tension liquid, or a solid. If the scavenger is a liquid material, it may be incorporated into a solid material to be used as a scavenger. The capturing materials disclosed in U.S. Pat. No. 6,254,942 to Tanaka, e.g., phosphoric acid, potassium carbonate, and active carbon, may be used in manufacturing scavenger components. The description at column 3, lines 1-43, of the Tanaka patent are incorporated by reference herein. In addition, the molecular sieves disclosed in U.S. Patent Application Publication No. 2004/0137339 to Zhang et al. may be used in manufacturing scavenger components. The description in paragraphs [0037]-[0047] of the Zhang et al. publication are incorporated by reference herein.

In one embodiment of the invention, the scavenger component may be manufactured from an article comprising glass and/or ceramics, e.g., oxides of aluminum, boron, cerium, cobalt, cupper, erbium, hafnium, lanthanum, neodymium, praseodymium, scandium, silicon, titanium, yttrium, zirconium, mixtures thereof, and the like. Some examples of glass and/or ceramic materials include silica (SiO₂), fluorinated silica, zirconia (ZrO₂), silica-zirconia (SiO₂—ZrO₂), titania (TiO₂), silica-titania (SiO₂—TiO₂), hafnium oxide (HfO₂), yttria (Y₂O₃), silica-yttria (SiO₂—Y₂O₃), alumina (Al₂O₃), silica-alumina (SiO₂—Al₂O₃), silica-boron oxide (SiO₂—B₂O₃), mixtures thereof, and the like. Metal oxides suitable for preparation of the scavenger components are not limited to oxides having stoichiometric metal to oxide ratios. Metal oxides having stoichiometrically excess or deficient oxide to metal ratios may also be used in preparation of the scavenger components. Amorphous or alternative crystal forms of the metal oxides may also be used in manufacturing of the scavenger components.

Another example of a suitable scavenger material is commercially available porous glass, having a composition of about 96 weight percent silica, sold by Corning Inc., of New York, under the trademark Vycor RTM 7930. This glass has an average pore size of 0.004 micrometer, and a CTE of 0.75 ppm/° C. This porous glass has a large inner surface area of 250 m²/g and thereby can effectively scavenge both water vapor and hydrocarbons from the pellicle space. The modulus of rupture of the porous glass is 41.4 MPa. However, this porous glass contains impurities, particularly Na, and its CTE is higher than that of more than 99.9% pure synthetic silica. This porous glass can be used to manufacture composite frames for photomask assemblies having less stringent material purity and CTE requirements, and it therefore is considered suitable for use in carrying out the invention. This glass also can be used as a support material for other oxides, disclosed above.

To achieve optimal scavenging, the inner surface of the scavenger component preferably has a surface area larger than 10 m²/g, more preferably larger than 25 m²/g, and most preferably larger than 70 m²/g. The scavenger component is configured to scavenge harmful chemicals in an amount preferably greater than 0.01 weight percent of its own weight, and more preferably greater than 0.03 weight percent of its own weight.

In addition, the scavenger component preferably has sufficient fracture strength to withstand manual handling or stresses that might arise during the composite frame's preparation, including its processing and incorporation into the frame and the photomask assembly, and during the manufacturing of the electronic chip. To achieve this requisite strength, the scavenger component's elastic modulus is preferably greater than 1 GPa, more preferably greater than 5 GPa, and most preferably greater than 10 GPa, and its modulus of rupture is preferably greater than 1 MPa, more preferably greater than 5 MPa, and most preferably greater than 10 MPa.

In one embodiment of the invention, the scavenger component may be configured to have a high gas permeability, to facilitate an efficient purging of harmful chemicals from the pellicle space with an inert gas such as nitrogen. To remove the harmful chemicals by purging within a reasonable processing time period, the permeability of the porous scavenger component to nitrogen or oxygen preferably is higher than 10 ml·mm/cm²·min·MPa, more preferably is higher than 40 ml·mm/cm²·min·MPa, and most preferably is higher than 70 ml·mm/cm²·min·MPa. This high gas permeability can be achieved by preparing the scavenger component to have pores having average pore sizes preferably larger than 0.001 micrometers, more preferably larger than 0.01 micrometers, and most preferably larger than 0.08 micrometers. To prevent particles present in the environment surrounding the photomask assembly from migrating into the pellicle space, the average pore size of the scavenger component preferably is less than 10 micrometers, or more preferably less than 1 micrometer. Thus, the average pore size of the scavenger component preferably is in the range of 0.001 to 10 micrometers, more preferably in the range of 0.01 to 1 micrometers, and most preferably in the range of 0.08 micrometer to 1 micrometer.

The pore structure of the scavenger component or the metallic frame may be characterized using nitrogen-adsorption equipment, model name Tristar, manufactured by Micromeritics Instrument Corporation, of Norcross, Ga. A mercury porosimeter, manufactured by this same company under the model name AutoPore III, also may be used to characterize the pore structure of the scavenger component or the metallic frame. The modulus of rupture of the scavenger component may be measured using a mechanical strength analyzer, Model No. 4202, manufactured by Instron Corporation, of Norwood, Mass. The permeability of the scavenger component may be measured using a permeameter, Model No. G(E) 11142002-1135, manufactured by PMI (Porous Materials Inc.), of Ithaca, N.Y. The permeability measurements may be performed using nitrogen or oxygen. The definition of permeability and the permeability units used in this disclosure are explained, for example, in a publication by J. Brandrup et al., Polymer Handbook Fourth Edition, John Wiley & Sons, Inc. New York, N.Y., 1999, pages VI/543-VI/569.

The scavenger components may be prepared by cutting the porous articles using suitable machining processes, including laser machining, water jet machining, diamond tool machining, and ultrasonic milling. The articles may be directly cut into a final desired scavenger component shape as one piece. The scavenger components also may be manufactured by cutting the articles into thin rectangular bars and then attaching the bars together using laser welding or using adhesives suitable for the photomask assemblies. After these initial machining steps, the scavenger components may be further machined and polished to meet the dimensional and flatness specifications of the photomask assembly industry.

The porous articles for the scavenger components may be manufactured by variety of processes known to the industry. Exemplary processes are described in the following publications: Kingery et al., “Introduction to Ceramics,” (John Wiley and Sons, 1976); King, “Ceramic Technology and Processing,” (Noyes Publications, 2002); Murata, “Handbook of Optical Fibers and Cables,” (Marcel Dekker, 1996); and Brinker et al., “Sol-Gel Science,” (Academic Press, 1990). These processes include hand shaping, compacting, uniaxial pressing, hot pressing, hot isostatic pressing (HIP), injection molding, slip casting, tape casting, transfer molding, extrusion, chemical vapor deposition, and sol-gel processing. In an alternative process, Vycor RTM 7930 glass is prepared by etching a multicomponent glass, to increase the silica content of the glass to 96% and to cause the formation of pores having an average size of 0.004 micrometer.

These processes also may use high pressures and temperatures to compact powders and slurries. In these processes, dry or slightly damp powders, slurries, or colloidal solutions can be shaped into a plate, a rod, or a frame using a suitable mold or die. The articles thereby obtained may be dried, to remove volatile species such as water, alcohol, and acids used in their preparation. These articles also may be fired, to remove binders or additives used in their preparation. The firing also increases the mechanical strength of the article. The porous articles may be cut into the scavenger component shape at any step of these processes.

The sol-gel process is especially suitable for preparing scavenger component articles. This process provides the flexibility to produce very high-purity articles having controllable permeability and controllable pore structure over a wide range of pore size and inner surface area, and further having desired mechanical properties.

As disclosed above, for some composite metal/scavenger pellicle frame configurations, it might be desirable to maximize the scavenger component volume and minimize the volume of the metal, to provide greater scavenging performance. However, this maximization is limited by the mechanical properties of the metallic frame, which if unduly thin might have insufficient strength to withstand the stresses encountered during mask assembly and disassembly operations. Conversely, if the metallic frame is unduly thick, the volume of scavenger may thereby be reduced to a level that the scavenging of the harmful chemicals may become inadequate. Thus, the ratio of amount of the scavenger component to amount of the metallic frame should be in a particular range to enable the composite frame to effectively scavenge the harmful chemicals from the pellicle space yet at the same time have sufficient mechanical strength. The volume percentage of the scavenger component relative to the composite frame's overall volume preferably is in the range of 0.1 to 95%, more preferably, 1 to 80%, more preferably still 10 to 70%, and most preferably 20 to 60%.

To retain sufficient strength and rigidity, the metallic frame should have a cross-sectional thickness of preferably at least 100 micrometers, more preferably at least 500 micrometers, and most preferably at least 1,000 micrometers, in all directions. The exact cross-sectional thickness needed should be determined empirically.

The photomask assembly of the present invention can be better understood by reference to the following illustrative examples:

### EXAMPLE 1

### Metal Pellicle Frame and Machining of Windows

The following detailed description is an example of a composite pellicle frame configuration incorporating a through-machined window in each of its four sides, each window having a stepped shape and screwed flanges to hold a scavenger component in place. Such a pellicle frame is depicted in FIG. 2(d) and FIG. 4.

The machined metallic skeleton is formed from a standard metal pellicle frame. The type of frame (part number) is selected by the mask manufacturer based on the size of the reticle. The frame advantageously can have a black anodized finish. In constructing this embodiment of a pellicle frame, the windows preferably are machined prior to any such surface treatment.

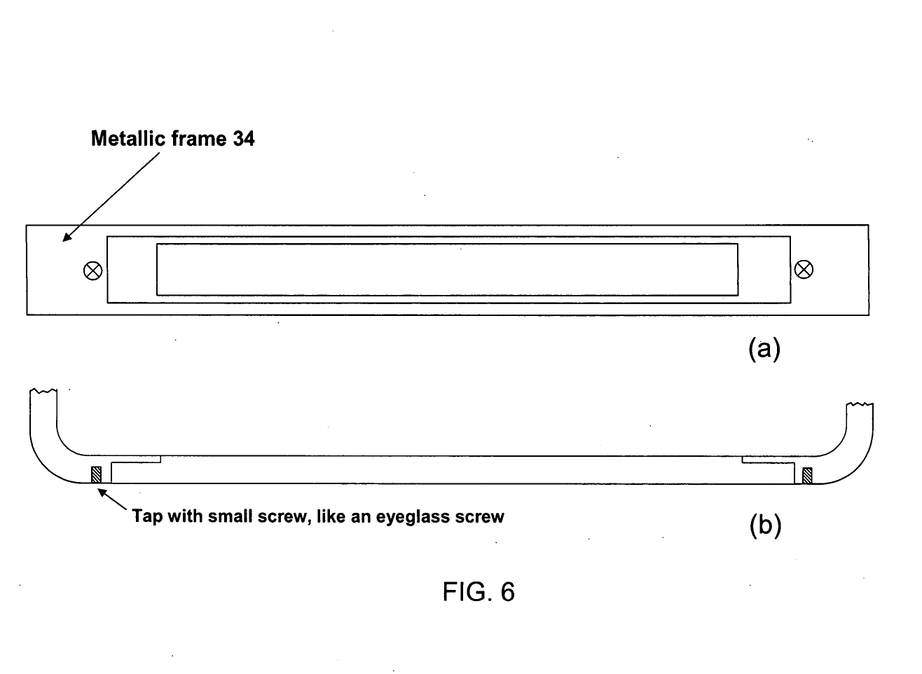

As shown in FIG. 6, a window is machined into each of the pellicle frame's four side walls. The size of each window is determined with two objectives in mind: (1) retaining sufficient mechanical properties of the metallic frame; and (2) maximizing the amount of scavenger to maximize scavenging capacity. The former objective takes precedence in determining the shape and size of windows and corresponding components.

In the frame's four corners, at least 3 mm in each direction from the corner apex should not be machined. Also, the windows are machined such that the metal wall thickness can withstand stresses that might occur during the manufacturing and the use of the photomask assembly. The minimum wall thickness required to achieve this strength should be determined empirically, but it is expected that it should be at least about 100 micrometers. The height of the windows also is governed by the need for strength and rigidity. This height should be determined empirically, but it is expected that at least about 100 micrometers of metal should be retained at the upper and lower edges of the inner frame wall.

### EXAMPLE 2

### Processing of Scavenger Components by Sol-Gel Process

In this example, a sol-gel process is used to prepare a silica scavenger component. In this process, a sol is prepared using hydrolyzed silicon alkoxide and fine silica particles (fumed silica, e.g., Aerosil OX-50 manufactured by Degussa Corporation, of Parsippany, N.J.), as described in published U.S. Patent Application Publication No. 2002/0157419 A1 to Ganguli et al., which is incorporated by reference herein. The wet gel obtained by gelation of this sol then is dried using a sub-critical drying process described in U.S. Pat. No. 5,473,826 to Kirkbir et al. This drying process minimizes shrinkage of the gel and decrease of pore size, and it also prevents cracking of the wet gel, which otherwise can occur during drying. Because the gel does not significantly shrink during drying, large crack-free monolithic porous articles having specified pore structures can be easily obtained.

In one embodiment of this example of the invention, the dried gel then is partially densified to increase the mechanical strength of the porous article. The partial densification may be carried out at a temperature in the range of 650 to 1,260° C., or more preferably 1,000 to 1,200° C., in a controlled atmosphere of helium, nitrogen, oxygen, and their mixtures. In one embodiment, this atmosphere is a mixture of oxygen with either nitrogen or helium, the mixture having an oxygen concentration in the range of 3 to 20%, or more preferably about 7%. The gel is heated to a partial densification temperature at a rate in the range of 1 to 200° C./hr. More preferably, the heating rate is in the range of 10 to 100° C./hr, and most preferably it is about 15° C./hr. The gel is held at this temperature for a duration sufficient to provide adequate strength and develop a desired pore structure, as discussed below.

In another embodiment of this example of the invention, this process may further include a hydrocarbon burnout step, optionally performed after the drying step, in which hydrocarbons and moisture adsorbed on the dry gel surface are removed by heating the dry gel to a temperature in the range of 150 to 300° C., or more preferably in the range of 170 to 250° C., in a controlled atmosphere of oxygen and nitrogen. This atmosphere may contain oxygen in an amount of 3 to 20%, or more preferably about 7%. The gel is heated to a hydrocarbon burnout temperature at a rate in the range of 1 to 200° C./hr. More preferably, the heating rate is in the range of 10 to 100° C./hr, and most preferably it is about 25° C./hr. The dwell time at the hydrocarbon burnout temperature is in the range of 0.25 to 48 hours, or more preferably in the range of 2 to 24 hours, or most preferably about 12 hours. The dry gel then is partially densified at a temperature in the range of 650 to 1,260° C., or more preferably in the range of 1,000 to 1,200° C., in a controlled atmosphere of helium, oxygen, nitrogen, or mixtures of such gases. The gel is held at this temperature for a duration sufficient to provide a desired strength and to develop a desired pore structure, as discussed below.

This process may further include a halogenation step, optionally performed after the steps of drying and hydrocarbon burnout described above, in which the gel is heated over a range of temperatures in the range of preferably 500 to 1,200° C., more preferably 650 to 1,050° C., or most preferably 650 to 950° C. The halogenation step uses a heating rate preferably in the range of 10 to 200° C./hr, or most preferably about 25° C./hr. The gel may be held at the halogenation temperature for duration of about 1 hour.

The halogenation may be carried out at atmospheric pressure using a mixture of a halogenation agent and an inert gas, such as helium or nitrogen. Examples of suitable halogenation agents are chlorine (Cl₂), thionyl chloride (SOCl₂), carbon tetrachloride (CCl₄), fluorine (F₂), silicon tetrafluoride (SiF₄), carbon tetrafluoride (CF₄), nitrogen trifluoride (NF₃), sulfur hexafluoride (SF₆), hydrochloric acid (HCl), hydrofluoric acid (HF), and mixtures of these agents. Preferred halogenation agents are chlorine, thionyl chloride, and nitrogen trifluoride. The concentration of halogenation agent in the atmosphere may be in the range of 0.1 to 100%, or more preferably about 33%. The halogenation process is carried out to remove hydroxyl (OH) ions and other impurities.

The dry gel then is partially densified at a temperature in the range of 650 to 1,260° C., or more preferably 1,000 to 1,200° C., in a controlled atmosphere of helium, oxygen, nitrogen, or mixtures of such gases. This atmosphere may be a mixture of oxygen and either nitrogen or helium, the mixture having an oxygen concentration in the range of 3 to 20%, or more preferably about 7%. The gel is held at this temperature for a duration sufficient to provide a desired strength and a desired pore structure, as discussed below.

The process may further include a step, optionally performed after the steps of drying, hydrocarbon burnout, and halogenation, described above, in which the halogenated gel is oxygenated using methods known in the art to remove halogen species remaining in the gel, and it is then re-halogenated. This step helps to remove additional impurities. The dry gel then is partially densified at a temperature in the range of 650 to 1,260° C., or more preferably 1,000 to 1,200° C., in a controlled atmosphere of helium, oxygen, nitrogen, or mixtures of such gases. This atmosphere preferably is a mixture of oxygen and either nitrogen or helium, the mixture having an oxygen concentration in the range of 3 to 20%, or more preferably about 7%. The gel is held at this temperature for a duration sufficient to provide the desired strength and to develop a desired pore structure, as discussed below.

Based on the particular combination of temperature and time duration for the specified partial densification step, porous silica glasses can be obtained exhibiting either lower strength but larger inner surface area and higher permeability, or higher strength but smaller inner surface area and lower permeability. That is, the duration and temperature of the partial densification step are selected to achieve the proper balance of gas permeability and inner surface area with mechanical strength, as required by a given application. FIGS. 2 and 3 of U.S. Patent Application Publication No. 2004/0151990 to Ganguli et al. show, by way of example, the effects of partial densification temperature and time on permeability, inner surface area, and the modulus of rupture. In particular, the duration of this partial densification preferably is in the range of 5 minutes to 48 hours, more preferably in the range of 1 to 30 hours, and most preferably about 4 hours.

The resulting porous article then is machined to the appropriate final dimensions of the desired scavenger component. The scavenger component may be produced as close as possible in size to that of the machined windows described in Example 1.

The porous article can be machined using conventional processes, such as diamond turning, laser machining, water jet machining, and sonic milling. The porous article can be machined to directly provide the scavenger component with its final dimensions and shape. The scavenger component alternatively can be prepared by cutting the porous article into rectangular bars and then attaching the bars together using suitable adhesives or using laser welding to obtain the scavenger component's final dimensions and shape.

In a more detailed feature of the method for making a pellicle frame in accordance with the invention, the final partial densification step can be preceded by a step of subjecting the dry gel to an annealing temperature that is as much as about 300° C. lower than the initial partial densification temperature. This annealing step removes stresses that might have developed in the article during machining. Finally, the annealed porous article is heated to the final partial densification temperature, to produce the desired scavenger component. The final partial densification temperature is in the preferred range of 650 to 1,260° C., or more preferably 1,000 to 1,200° C. The gel is held at this final partial densification temperature for a duration sufficient to provide a desired strength and to develop a desired pore structure, depending on the application, as discussed above.

In additional aspects of the method for making a composite pellicle frame in accordance with the invention, the step of machining can be partly or completely avoided if the step of preparing the dry gel incorporates a molding process known in the sol-gel industry as a “net-shaping” or “near-net-shaping.” These molding processes can be used after experimental determination of the level of shrinkage of the particular gel caused by processing from gelation to partial densification. The gel, formed by gelation of sol, assumes the inner dimensions of the mold. After the level of shrinkage caused by processing has been experimentally determined, the final dimensions of the gel after partial densification can be predicted. In this aspect of the method, sols are cast into molds having shapes and inner dimensions determined by the above-described shrinkage experimentation, such that when the gels obtained from such molds are dried and then directly (i.e., without machining or intermediate machining) partially densified, they yield articles having dimensions substantially identical to that required, without the need for the step of machining of the articles.

Gels usually experience linear shrinkage in the range of 6 to 10% through aging and moderate pressure drying (MPD). Consequently, if these gels are used as scavenger components in the as-dried condition (where the surface area of the as dried gel is in the range of 300 to 1,000 m²/g), the molds should be oversized by about 6 to 10%. If these gels are to be partially sintered, on the other hand, additional shrinkage will occur and the molds must be made correspondingly larger. Gels can shrink about 37% from cast gel to sintering at about 1,180° C. Total shrinkage from cast gel to glass can vary in the range of 42 to 65%.

### EXAMPLE 3

### Silica Scavenger Component

In this example, a sol-gel process is used to prepare a silica scavenger component. A sol was prepared using the method disclosed in Example 2 of U.S. Patent Application Publication No. 2002/0157419 A1 to Ganguli et al. This sol was cast into a square mold having inner dimensions of about 26.7 cm×26.7 cm, to a height of about 18 mm. After gelation, the gel was subcritically dried according to techniques disclosed in U.S. Pat. No. 5,473,826 to Kirkbir et al. The dried gel was free of any cracks.

To perform partial densification of the dry gel, the gel was placed in an electrically heated SiC furnace having a quartz enclosure. First, hydrocarbons and water vapor adsorbed on the dry gel surface were removed by heating the gel in an atmosphere containing about 7% oxygen and about 93% nitrogen. In this step, the gel was first heated from about 20° C. to about 170° C., at a heating rate of about 25° C./hr, and the gel then was held at about 170° C. for about 5 hours. The gel then was further heated from about 170° C. to about 250° C., at a heating rate of about 5° C./hr. The dry gel then was held at about 250° C. for about 12 hours.

After the hydrocarbon removal step, the dry gel was heated in the same atmosphere, at a rate of about 25° C./hr, to a temperature of about 650° C. The gel was then halogenated by heating it from about 650° C. to about 1,050° C., at the same rate of about 25° C./hr, in an atmosphere of about 33% chlorine-helium. The gel was held at about 1,050° C. for about 1 hour, for further halogenation. The atmosphere then was changed to be about 7% oxygen-helium, and the gel was partially densified by heating the gel from about 1,050° C. to about 1,100° C., at a heating rate of about 25° C./hr, and by holding the gel at about 1,100° C. for about 4 hours. The partially densified dry gel then was cooled to the room temperature and the silica scavenger component is thereby prepared.

The pore structure of this silica component was characterized using nitrogen-adsorption equipment, model name Tristar, manufactured by Micromeritics Instrument Corporation. This component was measured to have a surface area of about 65.0 m²/g, total pore volume of about 0.55 cm³/g, and average pore size of about 8.55×10⁻³ micrometer.

The capability of the silica component for scavenging of the harmful chemicals was measured at a temperature of about 25° C., using a thermogravimetric analyzer, Model TGA 7, manufactured by Perkin Elmer, of Wellesley, Mass. In this measurement, the component was placed in the analyzer chamber, heated in dry nitrogen from about 25° C. to about 1,000° C., with a heating rate of about 40° C./min, and then held at 1,000° C. for about 1 hour. After the sample was cooled to about 25° C., the nitrogen purging was continued for about 30 hours. This dry nitrogen stream was then saturated with ethanol (or water) by diverting the stream through an ethanol (or water) bubbler before its entrance to the chamber. The weight of the silica component increased due to adsorption of ethanol (or water) on its surface. This bubbling was stopped after about an additional 120 minutes, by bypassing the bubbler and again introducing the dry nitrogen to the chamber. The amount of weight gain at the end of the measurement was due to amount of ethanol (or water) irreversibly adsorbed on the silica component surface. The silica component's ethanol-scavenging capability was about 0.41 weight percent, and its water-scavenging capability was about 0.06 weight percent.

As discussed above, although the investigations carried out to determine the cause of mask defects showed that some of the defects comprised organic material, the harmful chemicals that may cause such organic defects have not yet been well identified. In the absence of such knowledge, the ethanol scavenging capability was assumed to represent the organic scavenging capability of the component.

This silica component was further analyzed for its ammonia (NH₃) scavenging capability by using AutoChem II 2920 Chemisorption Analyzer, manufactured by Micromeritics Instrument Corporation. This analysis is carried out in three steps. In the first step, the component is heated in N₂ with a heating rate of about 10° C./min, from room temperature to about 500° C., to remove volatile compounds from the sample, and then it is cooled back to room temperature. In the second step, the component is exposed to about 10% NH₃—N₂ stream with a flow rate of about 25 ml/min for at least 1 hour, at room temperature. In the third step, the sample is heated with a heating rate of about 7.5° C./min from room temperature to about 500° C. During this heating, the amount of ammonia desorbed from the sample is measured. The total amount of the gas desorbed is assumed to be due to NH₃. As shown in Table 1, this analysis indicated that ammonia scavenging capability of this silica component was about 0.05 weight percent.

### EXAMPLE 4

### Silica Scavenger Components

A silica scavenger component was prepared and analyzed in the same manner as in Example 3, except that the gel was partially densified by holding it at about 1,140° C., instead of about 1,100° C. The porous glass had a surface area measured to be about 76.3 m²/g, and it had an average pore size measured to be about 0.09 micrometer.

The modulus of rupture of the scavenger component was measured using a mechanical strength analyzer, Model No. 4202, manufactured by Instron, of Canton, Massachusetts. The modulus of rupture was measured to be about 20.7±2.0 MPa. The permeability of the scavenger component was measured using a permeameter, Model No. G(E) 11142002-1135, manufactured by PMI (Porous Materials Inc.), of Ithaca, New York. The permeability to nitrogen was measured to be about 52.2 ml·mm/cm²·min·MPa, and the permeability to oxygen was measured to be about 46.0 ml·mm/cm²·min·MPa. The ethanol scavenging capability of this silica component was measured to be about 0.56 weight percent.

### EXAMPLE 5

### Silica Scavenger Components

A silica scavenger component was prepared and analyzed in the same manner as in Example 3, except that the gel was partially densified by holding it at about 1,180° C., instead of about 1,100° C. The scavenger component was measured to have a surface area of about 29.8 m²/g, a pore volume about 0.22 cm³/g, and an average pore size about 0.020 micrometer. It had a modulus of rupture measured to be about 39.1±6.7 MPa, and its permeability to nitrogen was measured to be about 94.3 ml·mm/cm²·min·MPa and its permeability to oxygen was measured to be about 76.5 ml·mm/cm²·min·MPa.

The ethanol scavenging capability of this silica component was measured to be about 0.21 weight percent, and its water scavenging capability was measured to be about 0.05 weight percent. As shown in Table 1, this analysis indicated that ammonia scavenging capability of this silica component was less than 0.01 weight percent, i.e., it was negligible.

This component was further analyzed for its scavenging capability for SO₃. The sample was initially degassed in a quartz tube furnace by heating it at about 100° C./hr up to about 200° C. and then holding it for about 4 hours in He. The component then was removed from the furnace and weighed. It was then placed back in the furnace and exposed to about 10% SO₃-90% He gas stream at about 1.0 liter/min flow rate for about 2 hours, at a temperature of about 50° C. The sample then was removed from the quartz furnace and re-weighed. The increase in weight was attributed to SO₃ adsorption. As shown in Table 1, this analysis indicated that SO₃ scavenging capability of this silica component was about 0.50 weight percent.

### EXAMPLE 6

### Silica Scavenger Components

A silica scavenger component was prepared and analyzed in the same manner as in Example 3, except that the gel was partially densified by holding it at about 1,220° C., instead of about 1,000° C. The component had a surface area measured to be about 18.4 m²/g and an average pore size measured to be about 0.08 micrometer. Its modulus of rupture was measured to be about 137.5±38.6 MPa, and its permeability to nitrogen was measured to be about 0.3 ml·mm/cm²·min·MPa and its permeability to oxygen was measured to be about 0.4 ml·mm/cm²·min·MPa. The ethanol scavenging capability of this silica component was measured to be about 0.12 weight percent.

### EXAMPLE 7

### Silica Scavenger Components

A silica scavenger component was prepared and analyzed in the same manner as in Example 1, except that the gel was partially densified by holding it at about 1,260° C., instead of about 1,100° C. The silica component had a surface area measured to be about 0.3 m²/g and an average pore size measured to be about 0.03 micrometer. It had a modulus of rupture measured to be about 121.7±20.0 MPa, and its permeability to nitrogen was measured to be about 0.1 ml·mm/cm²·min·MPa and its permeability to oxygen was measured to be about 0.5 ml·mm/cm²·min·MPa. The scavenging capability of this component was determined to be negligible.

Taken together, Examples 3 to 7 demonstrate that silica components having a wide range of pore structure and strength can be prepared by varying the temperature of the partial densification. These examples further demonstrate that the scavenging capability of the components increased with increasing surface area. The large surface area components, like one obtained in Example 3, would be most useful for applications in which high pore surface area is important and somewhat reduced strength is acceptable.

### EXAMPLE 8

### Yttria-Silica Scavenger Component

In this example, two yttria-silica scavenger components were prepared by following the procedure described in Example 3, except that yttria powder was added together with Aerosil OX-50 silica powder to the acidified de-ionized water at a pH of 2.0, and the gel was partially densified at about 1,180° C. instead of about 1,100° C. The yttria powder was purchased from Alfa Aesar, Ward Hill, Mass., catalog number 44048. The amount of yttria powder added was varied to prepare about 2 wt % (Example 8(a)) and about 10 wt % (Example 8(b)) yttria-silica scavenger components. As shown in Table 1, about 2 wt % yttria-silica scavenger component had a scavenging capability of about 0.04 wt % NH₃, whereas about 10 wt % yttria-silica scavenger component had a scavenging capability about 0.05 wt % NH₃, i.e., a slightly higher scavenging capability.

### EXAMPLE 9

### Yttria-Silica Scavenger Component

In this example, four yttria-doped silica scavenger components were prepared, as follows. Yttria content of these components were determined by using an X-ray fluorescence spectrometer, manufactured by Rigaku, The Woodlands, Tex., with a model name of ZSX 100e. In each example, the top surface of a dry gel sample (18 mm thick) was first analyzed. Thereafter, a portion having a thickness of about 1 mm was removed from the top surface of each sample, by grinding, and the ground surface then was analyzed. The results of these two analyses were averaged and reported as the yttria content of the particular sample. It was found that these gels contained about 3 wt % yttria.

A silica scavenger component was prepared in the same manner as in Example 3, except that the silica component was partially densified at about 1,180° C. instead of about 1,100° C. and was further processed after the partial densification to obtain a yttria-silica scavenger, as follows. First, the silica component was immersed in a container containing a mixture prepared by mixing a yttrium isopropoxide solution with iso-propanol (IPA) with a weight ratio of about 5 to about 95 (the “YIP-IPA mixture”). The yttrium isopropoxide solution comprised about 25 wt % yttrium isopropoxide (YIP) in toluene, purchased from Strem Chemicals Inc., Newburyport, Mass., catalog number 39-3000. Thereafter, the container was placed in an autoclave and heated for about 72 hours at about 140° C. The autoclave pressure increased to about 80 psig during this treatment. After the container was cooled to room temperature, the silica component was removed from the container and immersed in IPA for solvent-washing for at least 10 hours. Finally, the solvent-washed silica component was dried at about 50° C. for about 48 hours in an oven to obtain a yttria-silica scavenger component. The ammonia scavenging capability of this component was found to be about 0.13 weight percent.

A silica scavenger component was prepared in the same manner as in Example 3, except that the silica component was partially densified at about 1,180° C. instead of 1,100° C. and was further processed after the partial densification to obtain a yttria-silica scavenger, as follows. First, the silica component was immersed in a container containing the YIP-IPA mixture and maintained at about 20° C. for about 20 hours. Thereafter, the silica component was taken out of the container and immersed in IPA for solvent-washing for at least 10 hours. Finally, the solvent-washed silica component was dried at about 50° C. for about 48 hours in an oven to obtain a yttria-silica scavenger component. The ammonia scavenging capability of this component was found to be about 0.09 weight percent.

A silica scavenger component was prepared in the same manner as in Example 3, except that the silica component was partially densified at about 1180° C. instead of 1,100° C. and further processed after the partial densification to obtain a yttria-silica scavenger, as follows. First, the silica component was immersed in a container containing about 5 wt % yttrium 2-ethylhexanoate-IPA mixture. Yttrium 2-ethylhexanoate was purchased as powder from Strem Chemicals Inc., catalog number 39-2400. This powder was dissolved in IPA by heating to about 40° C. to prepare the mixture. After the immersion of the component, the container was placed in an autoclave and heated for about 72 hours at about 140° C. The autoclave pressure increased to about 120 psig during this treatment. After the container was cooled to room temperature, the silica component was taken out of the container and immersed in IPA for solvent-washing for at least 10 hours. Finally, the solvent-washed silica component was dried at about 50° C. for about 48 hours in an oven to obtain a yttria-silica scavenger component. The ammonia scavenging capability of this component was found to be about 0.04 weight percent.

A yttria-silica scavenger component was prepared by following the procedure described in Example 3, except that after the gelation step and before the drying step, the wet gel was immersed in a container containing the YIP-IPA mixture and heat-treated for about 72 hours at about 140° C. in an autoclave, and the dry gel was partially densified at about 1,180° C. instead of about 1,100° C. The ammonia scavenging capability of this component was found to be about 0.10 weight percent.

Taken together, Examples 8(a), 8(b), and 9(a) to 9(d) demonstrate that the yttria-silica scavenger components can be prepared by various processing approaches. Taken together, Examples 5, 8(a), 8(b), and 9(a) to 9(c) demonstrate that the scavenger components comprising yttria had better ammonia scavenging capability than that did scavenger components consisting essentially of only silica. For example, the silica scavenger component disclosed in Example 5, which is partially densified at about 1,180° C., had a surface area of about 29.8 m²/g but a negligible NH₃ scavenging capability, <0.01 wt %. However, doping the silica scavenger with a small amount of yttria considerably increased the component's NH₃ scavenging capability. As compared to the scavenger component disclosed in Example 5, although the 2 wt % Y₂O₃—SiO₂ scavenger component disclosed in Example 8(a) was partially densified at the same temperature, i.e., about 1,180° C., and although it had a similar surface area of about 30.0 m²/g, it had considerably higher NH₃-scavenging capability, i.e., about 0.04 wt %.

The Examples 9(a) to 9(c) confirmed this result. These components were also partially densified at the same temperature, about 1,180° C. and had comparable surface areas in the range of 8.5 to 22.4 m²/g, but these components, with only 3 wt % yttria doping, had a very good NH₃ scavenging capability, in the range of 0.04 to 0.13. Conversely, the component of Example 5, with no yttria doping, had negligible capability.

These results indicate that both the porous silica articles and the porous yttria-doped silica articles can be used as scavenger component materials. However, for the same amount of material, yttria-doped components may provide better scavenging capability for removal of NH₃. On the other hand, the components consisting essentially of only silica may have a very good harmful chemical scavenging capability for organics, water, and SO₃.

### EXAMPLE 10

### Zirconia-Silica Scavenger Components by Sol-Gel Process

Scavenger components prepared from as-dried zirconia-silica gels adsorbed considerably greater amounts of NH₃ due to their high porosity. These gels were prepared as follows. About 416.6 grams of tetralkoxy-silane was measured in a beaker. In a first step, about 134.6 grams of reagent grade ethanol was added to the beaker and mixed. In a second step, about 36.0 grams of about 0.2 N HCl was added to this mixture and mixed by a magnetic stirrer for about 1 hour. In a third step, about 405.6 grams of zirconium propoxide was quickly added to the mixture, and the mixture then was stirred for about one hour. In a fourth step, about 71.3 grams of 2,4-pentanedione was added to the mixture and mixed for about 10 minutes. In a fifth step, about 208.8 grams of deionized water was slowly added. After all water was added, the mixture was magnetically stirred for about 10 minutes. The resultant mixture was a clear, yellow-orange sol with relatively low viscosity. This sol was cast in a mold having a desired shape, gelled, and aged in an oven at about 35° C. for about 3 hours. The gel was then dried using a sub-critical drying process described in U.S. Pat. No. 5,473,826 to Kirkbir et al. This all alkoxide-derived component, having a composition of about 26 wt % ZrO₂—SiO₂ in the as-dried condition, showed about 0.5 wt % NH₃ scavenging capability. This example demonstrates that the components doped with zirconia can have a very good NH₃ removal capability.

### EXAMPLE 11

### Yttria-Silica Scavenger Components by Sol-Gel Process

Scavenger components prepared from as-dried yttria-silica gels also adsorbed considerably greater amounts of NH₃ due to their high porosity. These gels were prepared as follows. In a first step, about 275.96 grams of tetraethyl orthosilicate was mixed with about 89.72 grams of reagent-grade alcohol in a beaker and mixed with a magnetic stirrer. In a second step, about 24.00 grams of about 0.2 N HCl was added to this mixture and mixed using a magnetic stirrer for about 1 hour. In a third step, about 21.34 grams of about 25% yttrium isopropoxide-toluene mixture was added to the mixture and mixed for about 1 hour. In a fourth step, about 47.52 grams of acetyl acetone was added to the mixture and the mixture was stirred for about 10 minutes. In a fifth step, about 72.00 grams of 0.2 N HCl was added and the mixture was stirred for about 10 minutes. Thereafter, the final mixture was cast in a mold and gelled at about 35° C. within 24 hours. This gel was dried at atmospheric pressure and at about 120° C. within about 240 hours. This all alkoxide-derived component, having a composition of about 2 wt % Y₂O₃ SiO₂ in the as-dried condition, showed about 4.09 wt % NH₃ scavenging capability. This example demonstrates that the components doped with yttria can have a very good NH₃ removal capability.

Taken together, Examples 9(d), 10, and 11 show that as-dried gels can also be used for preparation of the components having very good scavenging capability, probably because of their very high surface areas, in the range of 332 to 961 m²/g, as compared to partially densified gels disclosed in previous examples.

Although the invention has been described in detail with reference only to the preferred articles and methods described above, those of ordinary skill in the art will appreciate that various modifications can be made without departing from the scope of the invention. Examples of such modifications include changes to the configuration of the composite frame, metallic frame material, the scavenger component material, the metallic frame and the scavenger component's permeability, porosity, and pore sizes, the scavenger component's scavenging capability as well as changes to the process steps related with manufacturing of the scavenger component and its incorporation into the metallic frame such as hydrocarbon burnout, halogenation, oxygenation, partial densification, and machining of articles. Accordingly, the invention is defined only by the appended claims.

TABLE 1
Pore Structure and Scavenging Capability of Components.

| | | | Pore Structure | | | | | | |
|---|---|---|---|---|---|---|---|---|---|
| | | Partial Densification | | | Average | Harmful Chemical | | | |
| Example | Scavenger | Temperature | Surface Area | Pore Volume | Pore Size | C₂H₅OH | H₂O | NH₃ | SO₃ |
| No. | Component | (° C.) | (m²/g) | (cm³/g) | (μm) | (wt %) | (wt %) | (wt %) | (wt %) |
| 3 | SiO₂ | 1,100 | 65.0 | 0.550 | 0.034 | 0.41 | 0.06 | 0.05 | — |
| 4 | SiO₂ | 1,140 | 76.3 | 0.860 | 0.090 | 0.56 | — | — | — |
| 5 | SiO₂ | 1,180 | 29.8 | 0.220 | 0.020 | 0.21 | 0.05 | <0.01 | 0.50 |
| 6 | SiO₂ | 1,220 | 18.4 | 0.180 | 0.080 | 0.12 | — | — | — |
| 7 | SiO₂ | 1,260 | 0.3 | <0.001 | 0.030 | 0.01 | 0.00 | — | — |
| 8 (a) | 2 wt % Y₂O₃—SiO₂ | 1,180 | 30.0 | 0.220 | 0.029 | — | — | 0.04 | — |
| 8 (b) | 10 wt % Y₂O₃—SiO₂ | 1,180 | 24.0 | 0.060 | 0.010 | — | — | 0.05 | — |
| 9 (a) | 3 wt % Y₂O₃—SiO₂ | 1,180 | 22.4 | 0.220 | 0.039 | — | — | 0.13 | — |
| 9 (b) | 3 wt % Y₂O₃—SiO₂ | 1,180 | | | | — | — | 0.09 | — |
| 9 (c) | 3 wt % Y₂O₃—SiO₂ | 1,180 | 8.5 | 0.082 | 0.039 | — | — | 0.04 | — |
| 9 (d) | 3 wt % Y₂O₃—SiO₂ | As dried | 332.0 | 1.312 | 0.016 | — | — | 0.10 | — |
| 10 | 26 wt % ZrO₂—SiO₂ | As dried | 759.0 | 1.850 | 0.010 | — | — | 0.50 | — |
| 11 | 2 wt % Y₂O₃—SiO₂ | As dried | 960.2 | 0.727 | 0.003 | — | — | 4.09 | — |

We claim:

1. A photomask assembly comprising:
a photomask substrate;
a composite frame; and
a pellicle;
wherein the composite frame comprises
a metallic frame component having a cross-sectional thickness of at least 100 micrometers in all directions, and
a scavenger component,
wherein the volume percentage of the scavenger component relative to the overall volume of the composite frame is in the range of 0.1 to 95%,
and wherein the scavenger component has a gas permeability to oxygen or nitrogen higher than about 10 ml·mm/cm²·min·MPa, an average pore size between 0.001 and 10 micrometers, and a pore surface area greater than 10 m²/g.

2. A photomask assembly as defined in claim 1, wherein the volume percentage of the scavenger component relative to the overall volume of the composite is in the range of 1 to 80%.

3. A photomask assembly as defined in claim 1, wherein the volume percentage of the scavenger component relative to the overall volume of the composite is in the range of 10 to 70%.

4. A photomask assembly as defined in claim 1, wherein the volume percentage of the scavenger component relative to the overall volume of the composite is in the range of 20 to 60%.

5. A photomask assembly as defined in claim 1, wherein the scavenger component comprises at least one metal oxide selected from the group consisting of oxides of aluminum, boron, cerium, cobalt, copper, erbium, hafnium, lanthanum, neodymium, praseodymium, scandium, silicon, titanium, yttrium, zirconium, and mixtures thereof.

6. A photomask assembly as defined in claim 1, wherein the scavenger component comprises at least one metal oxide selected from the group consisting of oxides of zirconium, yttrium, and mixtures thereof.

7. A photomask assembly as defined in claim 1, wherein the scavenger component comprises at least 0.1 weight percent oxide of yttrium.

8. A photomask assembly as defined in claim 1, wherein the scavenger component comprises at least 1 weight percent oxide of yttrium.

9. A photomask assembly as defined in claim 1, wherein the scavenger component comprises at least 10 weight percent oxide of yttrium.

10. A photomask assembly as defined in claim 1, wherein the scavenger component comprises at least 0.1 weight percent oxide of zirconium.

11. A photomask assembly as defined in claim 1, wherein the scavenger component comprises at least 1 weight percent oxide of zirconium.

12. A photomask assembly as defined in claim 1, wherein the scavenger component comprises at least 10 weight percent oxide of zirconium.

13. A photomask assembly as defined in claim 1, wherein the scavenger component has a gas permeability to oxygen or nitrogen greater than about 40 ml·mm/cm²·min·MPa.

14. A photomask assembly as defined in claim 1, wherein the scavenger component has a gas permeability to oxygen or nitrogen greater than about 70 ml·mm/cm²·min·MPa.

15. A photomask assembly as defined in claim 1, wherein the scavenger component has an average pore size between 0.01 and 1 micrometer.

16. A photomask assembly as defined in claim 1, wherein the scavenger component has an average pore size between 0.08 and 1 micrometer.

17. A photomask assembly as defined in claim 1, wherein the scavenger component has a pore surface area greater than 25 m²/g.

18. A photomask assembly as defined in claim 1, wherein the scavenger component has a pore surface area greater than 70 m²/g.

19. A photomask assembly as defined in claim 1, wherein the scavenger component is configured to scavenge at least one harmful chemical in an amount greater than 0.01 weight percent of the scavenger component.

20. A photomask assembly as defined in claim 1, wherein the scavenger component is configured to scavenge at least one harmful chemical in an amount greater than 0.03 weight percent of the scavenger component.

21. A photomask assembly as defined in claim 1, wherein the metallic frame comprises a metal selected from the group consisting of aluminum, steel, titanium, titanium alloys, molybdenum, nickel, nickel alloys, chromium, chromium alloys, copper, copper alloys, and mixtures thereof.

22. A photomask assembly as defined in claim 1, wherein the metallic frame consists essentially of aluminum.

23. A photomask assembly as defined in claim 1, wherein the cross-sectional thickness of the metallic frame is at least 500 micrometers in all directions.

24. A photomask assembly as defined in claim 1, wherein the cross-sectional thickness of the metallic frame is at least 1,000 micrometers in all directions.

25. A photomask assembly as defined in claim 1, wherein the metallic frame has a thermal expansion coefficient less than 20 ppm/° C.

26. A photomask assembly as defined in claim 1, wherein the metallic frame has a thermal expansion coefficient less than 10 ppm/° C.

27. A photomask assembly as defined in claim 1, wherein the metallic frame is porous.

28. A photomask assembly as defined in claim 1, wherein the metallic frame has a gas permeability to oxygen or nitrogen greater than about 10 ml·mm/cm²·min·MPa and an average pore size between 0.001 and 10 micrometers.

29. A photomask assembly as defined in claim 1, wherein the metallic frame has a gas permeability to oxygen or nitrogen greater than about 40 ml·mm/cm²·min·MPa.

30. A photomask assembly as defined in claim 1, wherein the metallic frame has a gas permeability to oxygen or nitrogen greater than about 70 ml·mm/cm²·min·MPa.

31. A photomask assembly as defined in claim 1, wherein the metallic frame has an average pore size between 0.01 and 1 micrometer.

32. A photomask assembly as defined in claim 1, wherein the metallic frame has an average pore size between 0.08 and 1 micrometer.

33. A photomask assembly as defined in claim 1, wherein:
the metallic frame component includes a recess; and
the scavenger component is sized to fit within the recess of the metallic frame component.

34. A photomask assembly comprising:
a photomask substrate;
a composite frame; and
a pellicle;
wherein the composite frame comprises
a metallic frame component, and
a scavenger component,
wherein the scavenger component comprises at least one metal oxide selected from the group consisting of oxides of aluminum, boron, cerium, cobalt, copper, erbium, hafnium, lanthanum, neodymium, praseodymium, scandium, silicon, titanium, yttrium, zirconium, and mixtures thereof,
and wherein the scavenger component has a gas permeability to oxygen or nitrogen greater than about 10 ml·mm/cm²·min·MPa, an average pore size between 0.001 and 10 micrometers, and a pore surface area greater than 10 m²/g.

35. A photomask assembly as defined in claim 34, wherein the scavenger component comprises at least one metal oxide selected from the group consisting of oxides of zirconium, yttrium, and mixtures thereof.

36. A photomask assembly as defined in claim 34, wherein the scavenger component comprises at least 0.1 weight percent oxide of yttrium or zirconium.

37. A photomask assembly as defined in claim 34, wherein the scavenger component comprises at least 1 weight percent oxide of yttrium or zirconium.

38. A photomask assembly as defined in claim 34, wherein the scavenger component comprises at least 10 weight percent oxide of yttrium or zirconium.
